(19) United States
(12) Patent Application Publication
(10) Pub. No.: US 2015/0228512 A1
(43) Pub. Date: Aug. 13, 2015

(54) SUBSTRATE TREATMENT METHOD, COMPUTER-READABLE STORAGE MEDIUM, AND SUBSTRATE TREATMENT SYSTEM

(71) Applicant: TOKYO ELECTRON LIMITED, Tokyo (JP)

(72) Inventors: Makoto Muramatsu, Koshi City (JP); Takahiro Kitano, Koshi City (JP); Tadatoshi Tomita, Koshi City (JP); Keiji Tanouchi, Nirasaki City (JP); Kazutoshi Yano, Koshi City (JP); Kenichi Shigetomi, Koshi City (JP); Akihiro Toyozawa, Koshi City (JP)

(21) Appl. No.: 14/430,574

(22) PCT Filed: Sep. 30, 2013
(86) PCT No.: PCT/JP2013/076511

§ 371 Date: Mar. 24, 2015

(30) Foreign Application Priority Data
Oct. 2, 2012 (JP) 2012-220819
Aug. 20, 2013 (JP) 2013-170120

(51) Int. Cl. H01L 21/67; H01L 21/311; H01L 21/687; B05C 11/08; B05C 9/14; H01L 21/3105; H01J 37/32

(52) U.S. Cl. CPC H01L 21/67098; H01L 21/67069; H01L 21/67023; H01L 21/67225; H01L 21/3105; H01L 21/31138; H01J 37/32889; B05C 11/08; B05C 9/14; H01L 21/68764; H01J 2237/334

(57) ABSTRACT

The present invention is a method of treating a substrate using a block copolymer containing a first polymer and a second polymer, the method including: a block copolymer coating step of applying the block copolymer onto a substrate or a base film applied on the substrate; and a polymer separation step of phase-separating the block copolymer into the first polymer and the second polymer by thermally treating the block copolymer on the substrate in a non-oxidizing gas atmosphere.

### TECHNICAL FIELD

The present invention relates to a substrate treatment method, a computer-readable storage medium, and a substrate treatment system, using a block copolymer containing a hydrophilic polymer having a hydrophilic property and a hydrophobic polymer having a hydrophobic property.

This application is based upon and claims the benefit of priority of the prior Japanese Patent Application No. 2012-220819, filed in Japan on Oct. 2, 2012, and the prior Japanese Patent Application No. 2013-170120, filed in Japan on Aug. 20, 2013, the entire contents of which are incorporated herein by reference.

### BACKGROUND ART

For example, in a manufacturing process of a semiconductor device, photolithography processing is performed in which a resist coating treatment of applying a resist solution onto, for example, a semiconductor wafer (hereinafter, referred to as a “wafer”) to form a resist film, exposure processing of exposing the resist film to a predetermined pattern, a developing treatment of developing the exposed resist film and so on are performed in sequence to form a predetermined resist pattern on the wafer. Then, using the resist pattern as a mask, an etching treatment is performed on a film to be treated on the wafer and a removal treatment of the resist film is then performed, to form a predetermined pattern in the film to be treated.

Incidentally, miniaturization of the above-described pattern of the film to be treated is required in recent years in order for higher integration of the semiconductor device. Therefore, miniaturization of the resist pattern is in progress and, for example, the wavelength of light for the exposure processing in the photolithography processing is being reduced. However, there are technical and cost limits in reducing the wavelength of an exposure light source, and it is now difficult to form a fine resist pattern at a level of, for example, several nanometers only by the method of increasingly reducing the wavelength of light.

Hence, there is a proposed wafer treatment method using a block copolymer composed of two kinds of chains (polymers) (Patent Document 1). In this method, first, a neutral layer having an intermediate affinity to the two kinds of polymers is formed as a base film on the wafer, and a guide pattern is formed, for example, of a resist on the neutral layer. Thereafter, the block copolymer is applied onto the neutral layer, and the block copolymer is phase-separated. Thereafter, one of the polymers is selectively removed, for example, by etching or the like to form a fine pattern composed of the other polymer on the wafer. Then, the pattern of the polymer is used as a mask, an etching treatment is performed on the film to be treated to form a predetermined pattern in the film to be treated.

### [Patent Document 1]

Japanese Patent Application Laid-open No. 2008-36491

### DISCLOSURE OF THE INVENTION

### Problems to be Solved by the Invention

Incidentally, the above-described block copolymer is gradually phase-separated by thermal treatment at a predetermined or higher temperature, so that polymers after phase separation are arrayed in a predetermined shape. Further, to promote the bonding of the polymers so as to increase the length of the pattern, it is necessary to diffuse the polymers, and to this end, it is necessary to thermally treat the polymers at a higher temperature.

However, it has been confirmed that when raising the thermal treatment temperature to elongate the pattern formed of the polymers, variations more likely to occur in the pattern formed of the phase-separated polymers with a higher temperature and a longer thermal treatment time.

The present inventors has inferred, from earnest study regarding the above point, that the variations of the pattern are caused from oxidization of the polymers of the block copolymer due to thermal treatment, oxidization of the neutral layer used as the base film, or oxidization of both of the polymers of the block copolymer and the neutral layer. Hence, when the thermal treatment to phase-separate the block copolymer was carried out in an atmosphere with a low oxygen concentration, it has been confirmed that oxidization of the polymers and the neutral layer as the base film can be prevented and a pattern without variations can be formed.

The present invention has been made in consideration of the above points and has an object to appropriately form a predetermined pattern on a substrate in a substrate treatment using a block copolymer containing a hydrophilic polymer and a hydrophobic polymer.

### Means for Solving the Problems

To achieve the above object, the present invention is a method of treating a substrate using a block copolymer containing a first polymer and a second polymer, the method including: a block copolymer coating step of applying the block copolymer onto a substrate or a base film applied on the substrate; and a polymer separation step of phase-separating the block copolymer into the first polymer and the second polymer by thermally treating the block copolymer on the substrate in a non-oxidizing gas atmosphere.

According to the present invention, in the polymer separation step, the block copolymer on the substrate is thermally treated in the non-oxidizing gas atmosphere. Accordingly, it is possible to prevent oxidization of the polymers of the block copolymer and the base film due to the thermal treatment so as to form a pattern without variations. Since a predetermined fine pattern can be appropriately formed on the substrate as described above, it is possible to appropriately perform the etching treatment on the film to be treated using the pattern of the hydrophilic polymer or the hydrophobic polymer as a mask, and form a predetermined pattern in the film to be treated.

The present invention according to another aspect is a computer-readable storage medium storing a program running on a computer of a control unit controlling a substrate treatment system to cause the substrate treatment system to perform the substrate treatment method.

The present invention according to still another aspect is a system for treating a substrate using a block copolymer containing a first polymer and a second polymer, the system including: a block copolymer coating apparatus that applies the block copolymer onto a substrate or a base film applied on the substrate; and a polymer separation apparatus that phase-separates the block copolymer into the first polymer and the second polymer by thermally treating the block copolymer on the substrate in a non-oxidizing gas atmosphere.

### Effect of the Invention

According to the present invention, a predetermined pattern can be appropriately formed on a substrate in a substrate treatment using a block copolymer containing a hydrophilic polymer and a hydrophobic polymer.

### BRIEF DESCRIPTION OF THE DRAWINGS

FIG. 1 An explanatory view illustrating the outline of a configuration of a substrate treatment system according to an embodiment.

FIG. 2 A plan view illustrating the outline of a configuration of a coating and developing treatment apparatus.

FIG. 3 A side view illustrating the outline of an internal configuration of the coating and developing treatment apparatus.

FIG. 4 A side view illustrating the outline of the internal configuration of the coating and developing treatment apparatus.

FIG. 5 A plan view illustrating the outline of a configuration of an etching treatment apparatus.

FIG. 6 A transverse sectional view illustrating the outline of a configuration of a polymer separation apparatus.

FIG. 7 A longitudinal sectional view illustrating the outline of the configuration of the polymer separation apparatus.

FIG. 8 A flowchart explaining main steps of a wafer treatment.

FIG. 9 An explanatory view of a longitudinal section illustrating an appearance that an anti-reflection film and a neutral layer are formed on a wafer.

FIG. 10 An explanatory view of a longitudinal section illustrating an appearance that a resist pattern is formed on the wafer.

FIG. 11 An explanatory view of a longitudinal section illustrating an appearance that a bared surface of a neutral layer on the wafer is hydrophilized.

FIG. 12 An explanatory view of a longitudinal section illustrating an appearance that a resist pattern is removed.

FIG. 13 An explanatory view of a longitudinal section illustrating an appearance that a block copolymer is applied on the wafer.

FIG. 14 An explanatory view illustrating a thermal treatment temperature in a polymer separation apparatus.

FIG. 15 An explanatory view of a longitudinal section illustrating an appearance that the block copolymer is phase-separated into a hydrophilic polymer and a hydrophobic polymer.

FIG. 16 An explanatory view of a plane illustrating the appearance that the block copolymer is phase-separated into the hydrophilic polymer and the hydrophobic polymer.

FIG. 17 An explanatory view of a longitudinal section illustrating an appearance that the hydrophilic polymer is removed.

FIG. 18 An explanatory view of a plane illustrating an appearance that a block copolymer is applied on a wafer on which a resist pattern has been formed in another embodiment.

FIG. 19 An explanatory view of a plane illustrating an appearance that the block copolymer is phase-separated into the hydrophilic polymer and the hydrophobic polymer in the another embodiment.

FIG. 20 An explanatory view of a longitudinal section illustrating an appearance that the hydrophobic polymer is removed.

FIG. 21 A longitudinal sectional view illustrating the outline of a configuration of a polymer separation apparatus according to another embodiment.

FIG. 22 A transverse sectional view illustrating the outline of a configuration of the polymer separation apparatus according to the another embodiment.

FIG. 23 An explanatory view illustrating an appearance that the wafer is delivered to a cooling plate.

FIG. 24 An explanatory view illustrating an appearance that the cooling plate is moved to above a hot plate.

FIG. 25 An explanatory view illustrating an appearance that the wafer is delivered from the cooling plate to raising and lowering pins.

FIG. 26 An explanatory view illustrating a state that the raising and lowering pins are kept in a state that the wafer is separated from the hot plate by a predetermined distance.

FIG. 27 An explanatory view illustrating a state that the wafer is delivered from the raising and lowering pins to the hot plate.

### BEST MODE FOR CARRYING OUT THE INVENTION

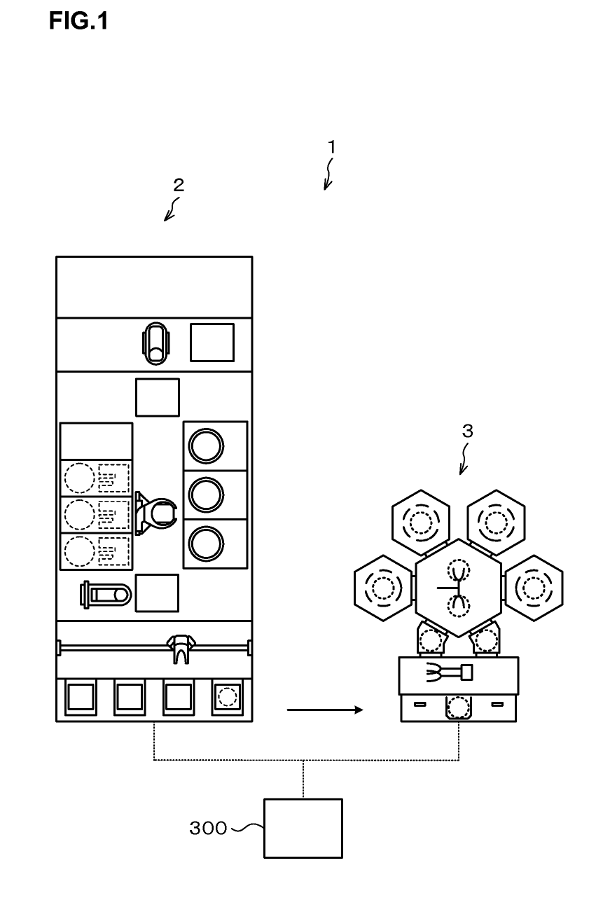

Hereinafter, an embodiment of the present invention will be described. FIG. 1 is an explanatory view illustrating the outline of a configuration of a substrate treatment system 1 according to this embodiment.

The substrate treatment system 1 has a coating and developing treatment apparatus 2 that performs photolithography processing on a wafer as a substrate and an etching treatment apparatus 3 that performs an etching treatment on the wafer as illustrated in FIG. 1. Note that a film to be treated (not illustrated) has been formed beforehand on the wafer to be treated in the substrate treatment system 1.

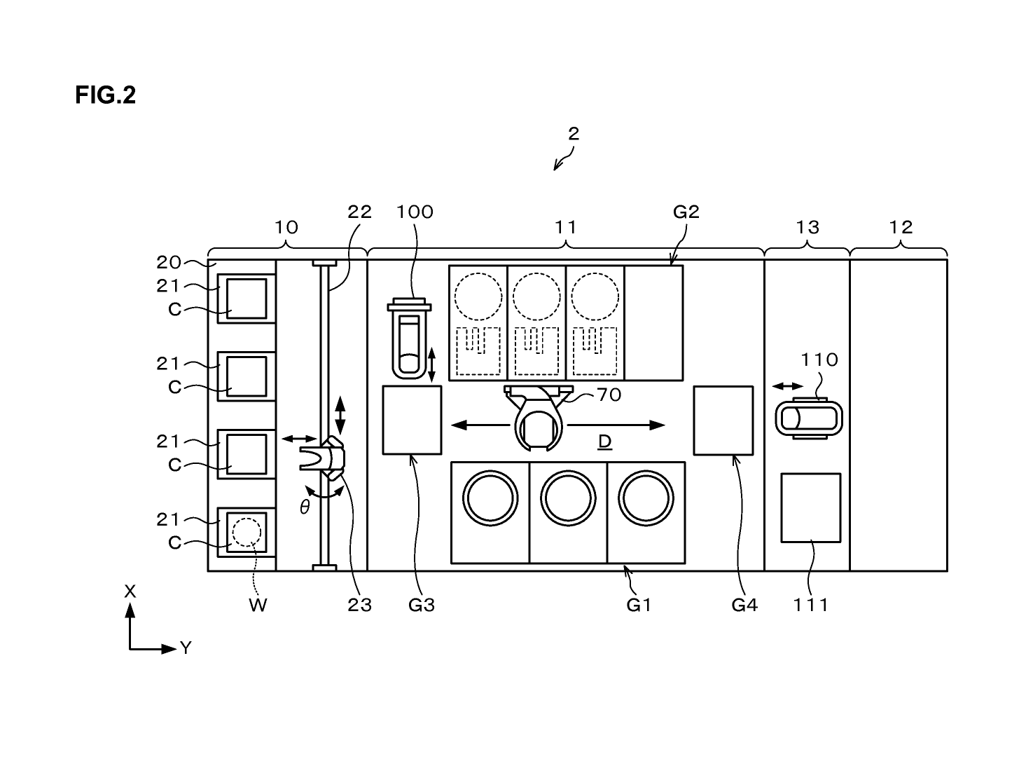

The coating and developing treatment apparatus 2 has, as illustrated in FIG. 2, a configuration in which, for example, a cassette station 10 to/from which a cassette C housing a plurality of wafers W is transferred in/out from/to the outside, a treatment station 11 which includes a plurality of various kinds of treatment apparatuses that perform predetermined treatments in a single-wafer manner in the photolithography processing, and an interface station 13 which delivers the wafer W to/from an exposure apparatus 12 adjacent to the treatment station 11, are integrally connected.

In the cassette station 10, a cassette mounting table 20 is provided. The cassette mounting table 20 is provided with, a plurality of, for example, four cassette mounting plates 21. The cassette mounting plates 21 are provided, arranged side by side in a line in an X-direction (a top-down direction in FIG. 2) that is the horizontal direction. On the cassette mounting plates 21, cassettes C can be mounted when the cassettes C are transferred in/out from/to the outside of the coating and developing treatment apparatus 2.

In the cassette station 10, a wafer transfer apparatus 23 is provided which is movable on a transfer path 22 extending in the X-direction as illustrated in FIG. 2. The wafer transfer apparatus 23 is movable also in a vertical direction and around a vertical axis (in a θ-direction), and can transfer the wafer W between the cassette C on each of the cassette mounting plates 21 and a later-described delivery apparatus in a third block G3 in the treatment station 11.

In the treatment station 11, a plurality of, for example, four blocks G1, G2, G3, G4 are provided each including various apparatuses. For example, the first block G1 is provided on the front side (X-direction negative direction side in FIG. 2) in the treatment station 11, and the second block G2 is provided on the rear side (X-direction positive direction side in FIG. 2) in the treatment station 11. Further, the third block G3 is provided on the cassette station 10 side (Y-direction negative direction side in FIG. 2) in the treatment station 11, and the fourth block G4 is provided on the interface station 13 side (Y-direction positive direction side in FIG. 2) in the treatment station 11.

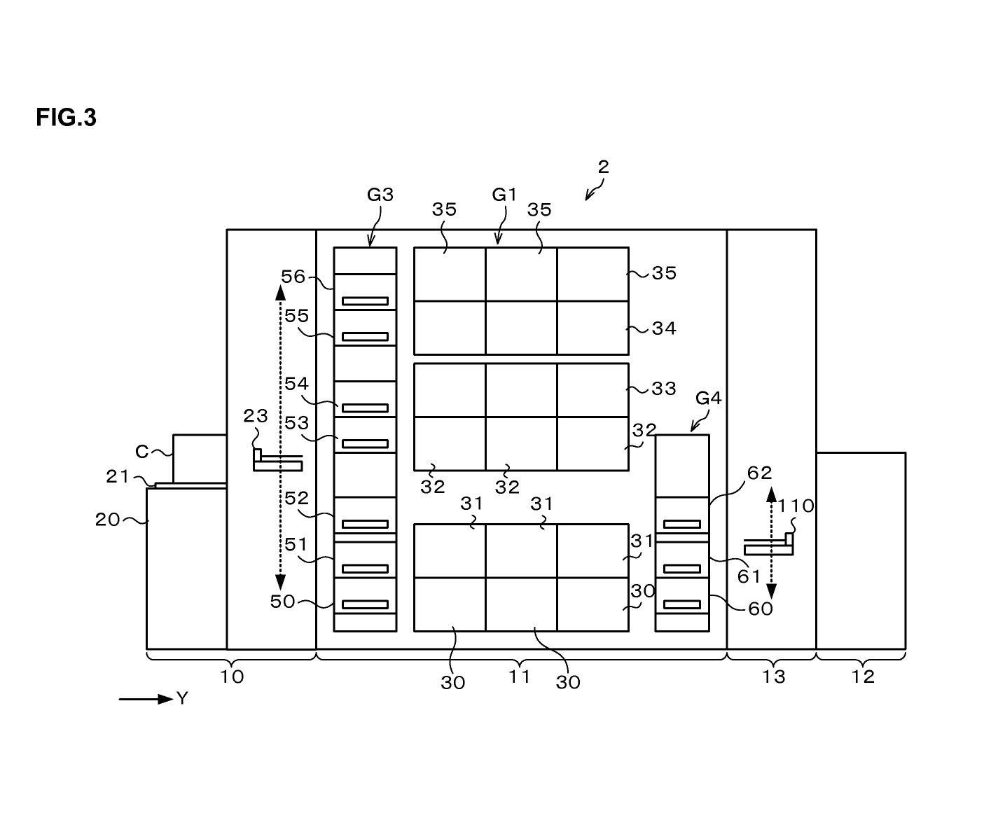

For example, in the first block G1, as illustrated in FIG. 3, a plurality of solution treatment apparatuses, for example, developing apparatuses 30 each of which performs a developing treatment on the wafer W, cleaning apparatuses 31 each of which applies an organic solvent onto the wafer W to clean the wafer W, anti-reflection film forming apparatuses 32 each of which forms an anti-reflection film on the wafer W, neutral layer forming apparatuses 33 each of which applies a neutralizing agent onto the wafer W to form a neutral layer as a base film, resist coating apparatuses 34 each of which applies a resist solution onto the wafer W to form a resist film, and block copolymer coating apparatuses 35 each of which applies a block copolymer onto the wafer W, are stacked in order from the bottom.

For example, three pieces of each of the developing apparatus 30, the cleaning apparatus 31, the anti-reflection film forming apparatus 32, the neutral layer forming apparatus 33, the resist coating apparatus 34, and the block copolymer coating apparatus 35 are arranged side by side in the horizontal direction. Note that the numbers and the arrangement of the developing apparatuses 30, the cleaning apparatuses 31, the anti-reflection film forming apparatuses 32, the neutral layer forming apparatuses 33, the resist coating apparatuses 34, and the block copolymer coating apparatuses 35 can be arbitrarily selected.

In the developing apparatus 30, the cleaning apparatus 31, the anti-reflection film forming apparatus 32, the neutral layer forming apparatus 33, the resist coating apparatus 34, and the block copolymer coating apparatus 35, for example, spin coating of applying a predetermined coating solution onto the wafer W is performed. In the spin coating, the coating solution is discharged, for example, from a coating nozzle onto the wafer W and the wafer W is rotated to diffuse the coating solution over the front surface of the wafer W.

Note that the block copolymer to be applied onto the wafer W in the block copolymer coating apparatus 35 has a first polymer and a second polymer. As the first polymer, a hydrophobic (nonpolar) polymer having a hydrophobic property (no polarity) is used, and as the second polymer, a hydrophilic (polar) polymer having a hydrophilic property (polarity) is used. In this embodiment, for example, polymethyl methacrylate (PMMA) is used as the hydrophilic polymer and, for example, polystyrene (PS) is used as the hydrophobic polymer. Further, the ratio of a molecular weight of the hydrophilic polymer in the block copolymer is, for example, 40% to 60%, and the ratio of a molecular weight of the hydrophobic polymer in the block copolymer is 60% to 40%. Besides, the block copolymer is a macromolecule in which the hydrophilic polymer and the hydrophobic polymer are linearly combined.

Further, the neutral layer formed on the wafer W in the neutral layer forming apparatus 33 has an intermediate affinity to the hydrophilic polymer and the hydrophobic polymer. In this embodiment, for example, a random copolymer or an alternating copolymer of polymethyl methacrylate and polystyrene is used as the neutral layer. Hereinafter, “neutral” means the case having the intermediate affinity to the hydrophilic polymer and the hydrophobic polymer as described above.

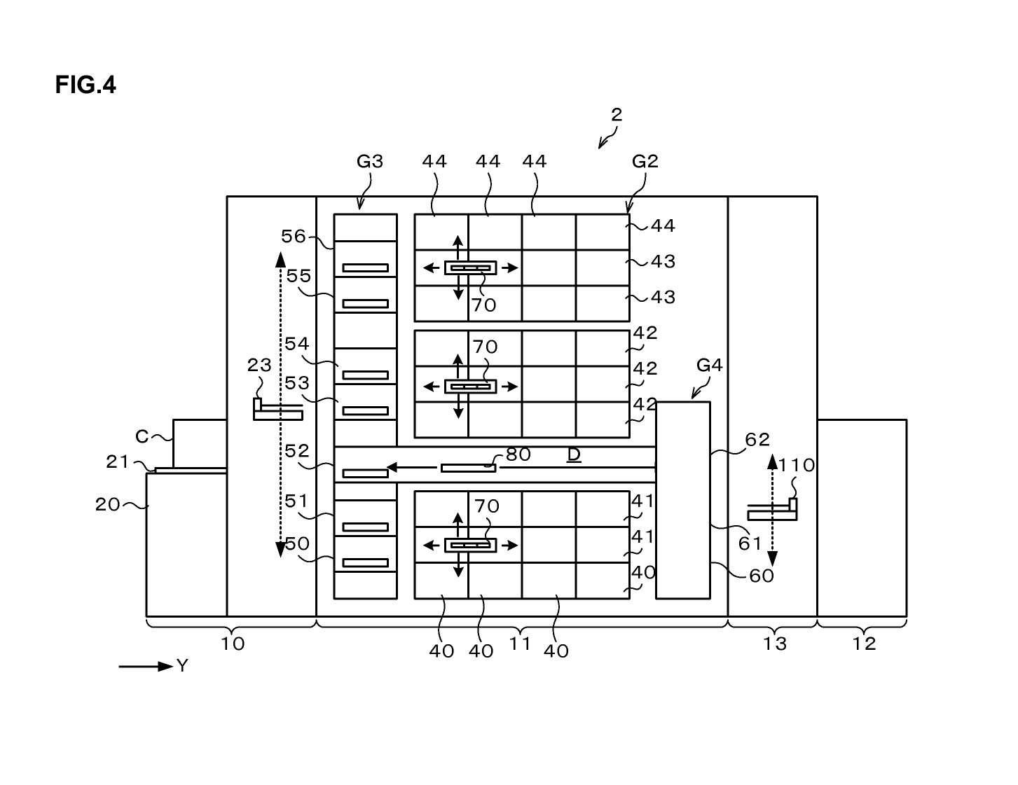

For example, in the second block G2, as illustrated in FIG. 4, thermal treatment apparatuses 40 each of which performs a thermal treatment on the wafer W, ultraviolet irradiation apparatuses 41 as neutral layer treatment apparatuses each of which applies ultraviolet light to the neutral layer on the wafer W to perform modification processing on the surface of the neutral layer, adhesion apparatuses 42 each of which performs a hydrophobic treatment on the wafer W, edge exposure apparatuses 43 each of which exposes the outer peripheral portion of the wafer W, and polymer separation apparatuses 44 each of which phase-separates the block copolymer applied on the wafer W in the block copolymer coating apparatuse 35 into the hydrophilic polymer and the hydrophobic polymer, are arranged side by side in the vertical direction and in the horizontal direction. The configuration of the polymer separation apparatus 44 will be described later. The thermal treatment apparatus 40 has a hot plate which mounts and heats the wafer W thereon and a cooling plate which mounts and cools the wafer W thereon, and thereby can perform both of a heat treatment and a cooling treatment. The ultraviolet irradiation apparatus 41 has a mounting table on which the wafer W is to be mounted and an ultraviolet irradiation unit which applies ultraviolet light with a wavelength of, for example, 172 nm to the wafer W on the mounting table. Besides, the numbers and the arrangement of the thermal treatment apparatuses 40, the ultraviolet irradiation apparatuses 41, the adhesion apparatuses 42, the edge exposure apparatuses 43, and the polymer separation apparatuses 44 can be arbitrarily selected.

For example, in the third block G3, a plurality of delivery apparatuses 50, 51, 52, 53, 54, 55, 56 are provided in order from the bottom. Further, in the fourth block G4, a plurality of delivery apparatuses 60, 61, 62 are provided in order from the bottom.

A wafer transfer region D is formed in a region surrounded by the first block G1 to the fourth block G4 as illustrated in FIG. 2. In the wafer transfer region D, for example, a wafer transfer apparatus 70 is arranged.

The wafer transfer apparatus 70 has a transfer arm that is movable, for example, in the Y-direction, the X-direction, the θ-direction, and the vertical direction. The wafer transfer apparatus 70 can move in the wafer transfer region D to transfer the wafer W to a predetermined apparatus in the first block G1, the second block G2, the third block G3 and the fourth block G4 therearound.

A plurality of the wafer transfer apparatuses 70 are arranged, for example, one above the other as illustrated in FIG. 4 and can transfer the wafers W, for example, to predetermined apparatuses in the blocks G1 to G4 at about the same levels as them.

In the wafer transfer region D, a shuttle transfer apparatus 80 is provided which linearly transfers the wafer W between the third block G3 and the fourth block G4.

The shuttle transfer apparatus 80 is configured to be linearly movable, for example, in the Y-direction. The shuttle transfer apparatus 80 can move in the Y-direction while supporting the wafer W, and transfer the wafer W between the delivery apparatus 52 in the third block G3 and the delivery apparatus 62 in the fourth block G4.

As illustrated in FIG. 2, a wafer transfer apparatus 100 is provided adjacent on the X-direction positive direction side of the third block G3. The wafer transfer apparatus 100 has a transfer arm that is movable, for example, in the X-direction, the θ-direction, and the vertical direction. The wafer transfer apparatus 100 can move up and down while supporting the wafer W to transfer the wafer W to each of the delivery apparatuses in the third block G3.

In the interface station 13, a wafer transfer apparatus 110 and a delivery apparatus 111 are provided. The wafer transfer apparatus 110 has a transfer arm that is movable, for example, in the Y-direction, the θ-direction, and the vertical direction. The wafer transfer apparatus 110 can transfer the wafer W to/from each of the delivery apparatuses in the fourth block G4, the delivery apparatus 111 and the exposure apparatus 12, for example, while supporting the wafer W by the transfer arm.

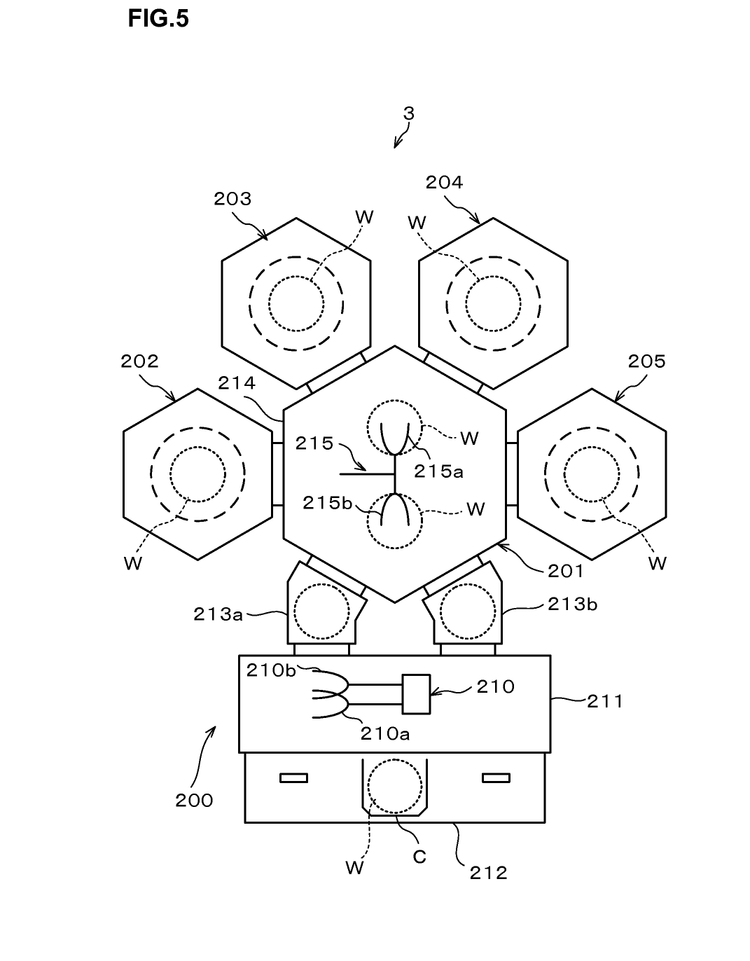

The etching treatment apparatus 3 has, as illustrated in FIG. 5, a cassette station 200 from/to which the wafer W is transferred into/out of the etching treatment apparatus 3, a common transfer unit 201 which transfers the wafer W, etching apparatuses 202, 203 as polymer removing apparatuses each of which performs an etching treatment on the block copolymer phase-separated on the wafer W to selectively remove either the hydrophilic polymer or the hydrophobic polymer, and etching apparatuses 204, 205 each of which etches the film to be treated on the wafer W into a predetermined pattern.

The cassette station 200 has a transfer room 211 in which a wafer transfer mechanism 210 which transfers the wafer W is provided. The wafer transfer mechanism 210 has two transfer arms 210a, 210b each of which substantially horizontally holds the wafer W, and is configured to transfer the wafer W while holding the wafer W by one of the transfer arms 210a and 210b. Beside the transfer room 211, a cassette mounting table 212 is provided on which a cassette C capable of housing a plurality of wafers W arranged side by side therein is mounted. In the illustrated example, a plurality of, for example, three cassettes C can be mounted on the cassette mounting table 212.

The transfer room 211 and the common transfer unit 201 are coupled to each other via two load-lock apparatuses 213a and 213b which can be evacuated.

The common transfer unit 201 has a transfer room chamber 214 having a hermetically closable structure formed, for example, in a substantially polygonal shape (a hexagonal shape in the illustrated example) as seen from above. In the transfer room chamber 214, a wafer transfer mechanism 215 which transfers the wafer W is provided. The wafer transfer mechanism 215 has two transfer arms 215a, 215b each of which substantially horizontally holds the wafer W, and is configured to transfer the wafer W while holding the wafer W by one of the transfer arms 215a and 215b.

Outside the transfer room chamber 214, the etching apparatuses 202, 203, 204, 205 and the load-lock apparatuses 213b, 213a are arranged to surround the periphery of the transfer room chamber 214. The etching apparatuses 202, 203, 204, 205 and the load-lock apparatuses 213b, 213a are arranged, for example, side by side in this order in the clockwise direction as seen from above and opposed to six side surface portions of the transfer room chamber 214 respectively.

Note that as the etching apparatuses 202 to 205, for example, RIE (Reactive Ion Etching) apparatuses are used. Namely, in each of the etching apparatuses 202 to 205, dry etching of etching the hydrophobic polymer or the film to be treated is performed, for example, with a reactive gas (etching gas) such as oxygen (O₂), ions, or radicals.

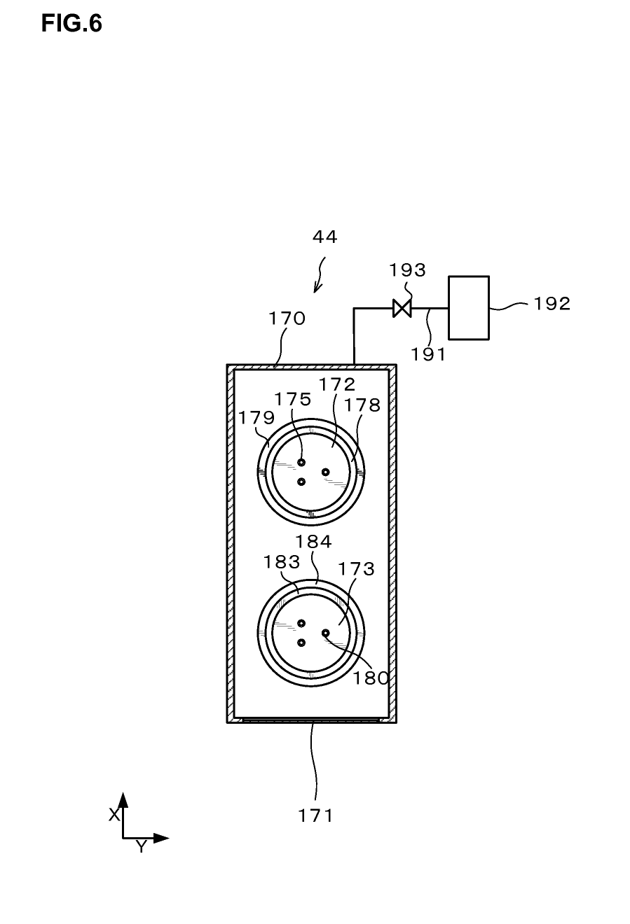

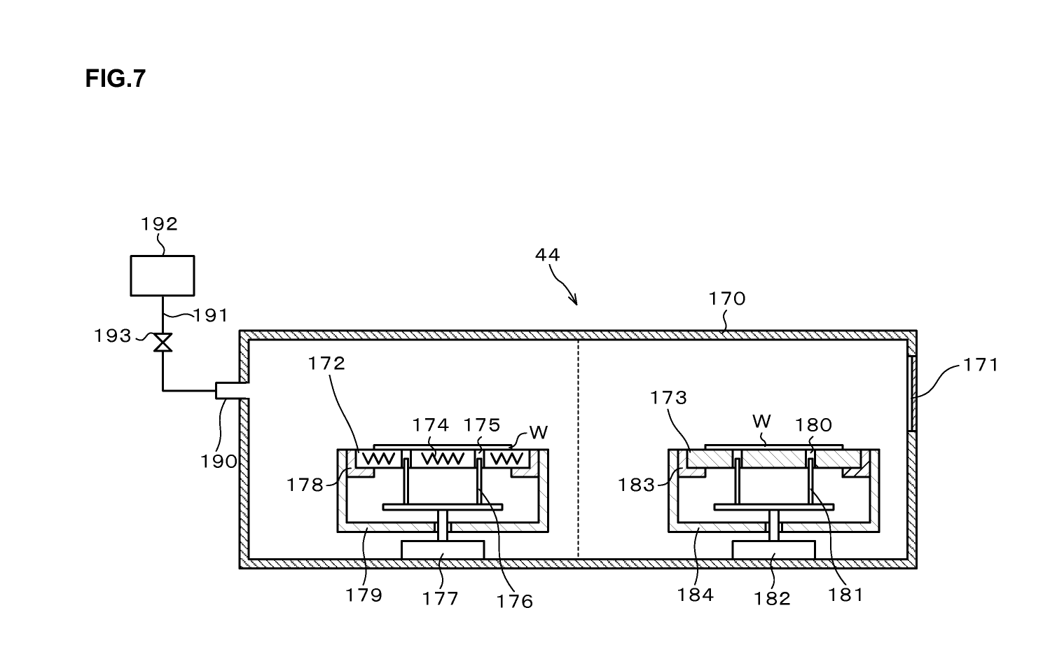

Next, the configuration of the above-described polymer separation apparatus 44 will be described. FIG. 6 is a transverse sectional view illustrating the outline of the configuration of the polymer separation apparatus 44. FIG. 7 is a longitudinal sectional view illustrating the outline of the configuration of the polymer separation apparatus 44.

For example, the polymer separation apparatus 44 has a treatment container 170 whose inside is closable, and a transfer-in/out port 171 for the wafer W formed in a side surface of the treatment container 170 facing the wafer transfer apparatus 70. Further, the polymer separation apparatus 44 is a thermal treatment apparatus that has, in the treatment container 170, a hot plate 172 that mounts and heats the wafer W thereon and a cooling plate 173 that mounts and temperature-regulates the wafer W thereon, and therefore can perform both a heating treatment and a cooling treatment.

The hot plate 172 has an almost thick disk shape. The hot plate 172 has a horizontal upper surface and, for example, a suction port (not illustrated) that sucks the wafer W is provided in the upper surface. By suction through the suction port, the wafer W can be suction-held on the hot plate 172.

Inside the hot plate 172, an electric heater 174 as a heating mechanism is provided as illustrated in FIG. 7 so that a later-described control unit 300 controls the supply amount of power to the electric heater 174 and thereby can control the hot plate 172 to a predetermined preset temperature.

The hot plate 172 is formed with a plurality of through holes 175 penetrating in the vertical direction thereof. In the through holes 175, raising and lowering pins 176 are provided. The raising and lowering pins 176 can move up and down by means of a raising and lowering drive mechanism 177 such as a cylinder. The raising and lowering pins 176 are inserted into the through holes 175 to be able to project from the upper surface of the hot plate 172 and rise and lower while supporting the wafer W.

The hot plate 172 is provided with an annular holding member 178 that holds the outer peripheral portion of the hot plate 172. The holding member 178 is provided with a cylindrical support ring 179 that surrounds the outer periphery of the holding member 178 and accommodates the raising and lowering pins 176.

The cooling plate 173 has an almost thick disk shape. The cooling plate 173 has a horizontal upper surface and, for example, a suction port (not illustrated) that sucks the wafer W is provided in the upper surface. By suction through the suction port, the wafer W can be suction-held on the cooling plate 173.

A cooling member (not illustrated) such as a Peltier element is embedded in the cooling plate 173 and can regulate the cooling plate 173 to a predetermined preset temperature.

The other configuration of the cooling plate 173 is the same as the configuration of the hot plate 172. More specifically, the cooling plate 173 is formed with a plurality of through holes 180 penetrating in the vertical direction thereof. In the through holes 180, raising and lowering pins 181 are provided. The raising and lowering pins 181 can move up and down by means of a raising and lowering drive mechanism 182 such as a cylinder. The raising and lowering pins 181 are inserted into the through holes 180 to be able to project from the upper surface of the cooling plate 173 and rise and lower while supporting the wafer W.

The cooling plate 173 is provided with an annular holding member 183 that holds the outer peripheral portion of the cooling plate 173. The holding member 183 is provided with a cylindrical support ring 184 that surrounds the outer periphery of the holding member 183 and accommodates the raising and lowering pins 181.

A side surface on the opposite side to the transfer-in/out port 171 of the treatment container 170 is formed with a gas supply port 190 that supplies a treatment gas into the treatment container 170. To the gas supply port 190, a gas supply source 192 is connected via a gas supply pipe 191. The gas supply pipe 191 is provided with a flow rate regulating mechanism 193 which can regulate the amount of the treatment gas supplied from the gas supply source 192 into the treatment container 170. The flow rate regulating mechanism 193 is controlled by the later-described control unit 300. As the treatment gas, a non-oxidizing gas that does not oxidize a hydrophilic polymer and a hydrophobic polymer when the wafer W is thermally treated so that the block copolymer applied on the wafer W in the block copolymer coating apparatus 35 is phase-separated into the hydrophilic polymer and the hydrophobic polymer. As the non-oxidizing gas, for example, gas containing no oxygen such as nitrogen gas, argon gas is used. Note that the configuration of the thermal treatment apparatus 40 is the same configuration as that of the polymer separation apparatus 44 except that the treatment container 170 is not formed with the gas supply port 190.

In the above substrate treatment system 1, the control unit 300 is provided as illustrated in FIG. 1. The control unit 300 is, for example, a computer and has a program storage unit (not illustrated). In the program storage unit, a program that controls the treatments on the wafer W in the substrate treatment system 1 is stored. The program storage unit further stores a program that controls the operations of the above-described various treatment apparatuses and a driving system such as transfer apparatuses to realize a later-described substrate treatment in the substrate treatment system 1. Note that the programs may be the ones which are recorded, for example, in a computer-readable storage medium such as a computer-readable hard disk (HD), flexible disk (FD), compact disk (CD), magneto-optical disk (MO), or memory card, and installed from the storage medium into the control unit 300.

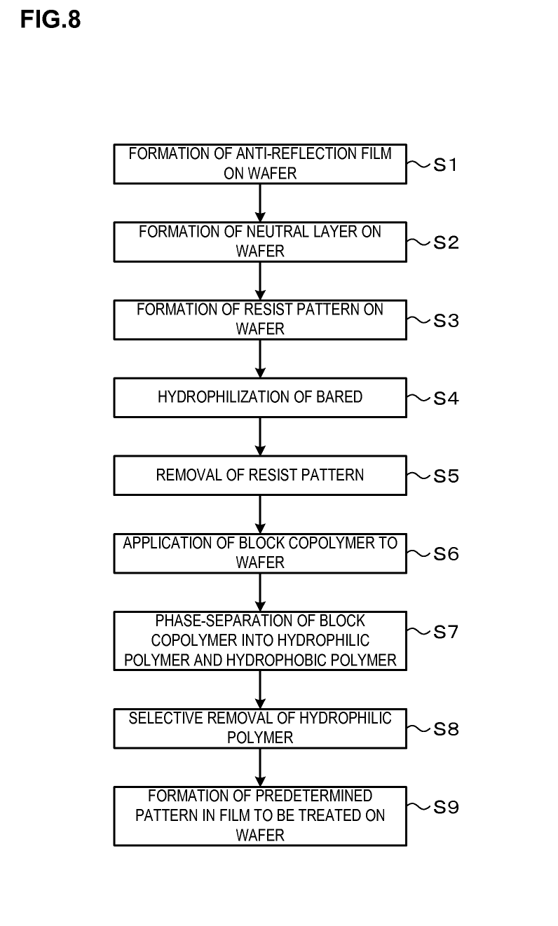

Next, a wafer treatment performed using the substrate treatment system 1 configured as described above will be described. FIG. 8 is a flowchart illustrating main steps of the wafer treatment.

First, the cassette C housing a plurality of wafers W is transferred into the cassette station 10 of the coating and developing treatment apparatus 2 and mounted on a predetermined cassette mounting plate 21. Then, the wafers W in the cassette C are sequentially taken out by the wafer transfer apparatus 23 and transferred to the delivery apparatus 53 in the treatment station 11.

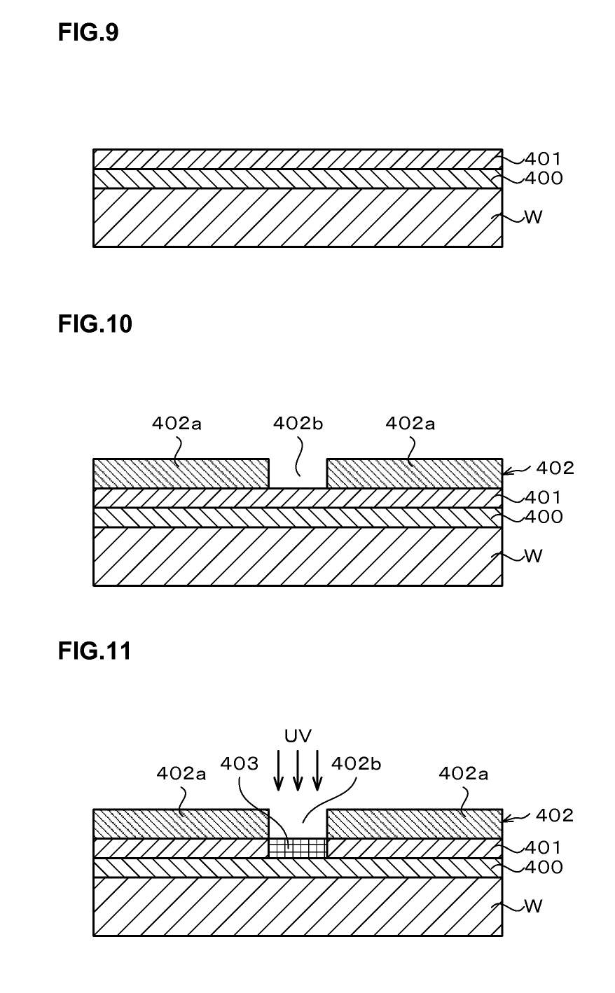

Then, the wafer W is transferred by the wafer transfer apparatus 70 to the thermal treatment apparatus 40 and temperature-regulated. Thereafter, the wafer W is transferred by the wafer transfer apparatus 70 to the anti-reflection film forming apparatus 32, in which an anti-reflection film 400 is formed on the wafer W as illustrated in FIG. 9 (Step S1 in FIG. 8). The wafer W is then transferred to the thermal treatment apparatus 40 and heated and temperature-regulated.

Then, the wafer W is transferred by the wafer transfer apparatus 70 to the neutral layer forming apparatus 33. In the neutral layer forming apparatus 33, the neutralizing agent is applied onto the anti-reflection film 400 on the wafer W as illustrated in FIG. 9 to form a neutral layer 401 as a base film (Step S2 in FIG. 8). Thereafter, the wafer W is transferred to the thermal treatment apparatus 40 and heated and temperature-regulated, and then returned to the delivery apparatus 53. Note that the heating temperature of the wafer W after the neutral layer 401 is formed in the thermal treatment apparatus 40 is preferably approximately 200° C. to 300° C., and for example, about 250° C. in this embodiment.

Then, the wafer W is transferred by the wafer transfer apparatus 100 to the delivery unit 54. Thereafter, the wafer W is transferred by the wafer transfer apparatus 70 to the adhesion unit 42 and subjected to an adhesion treatment. The wafer W is then transferred by the wafer transfer apparatus 70 to the resist coating apparatus 34, in which the resist solution is applied onto the neutral layer 401 to form a resist film. Thereafter, the wafer W is transferred by the wafer transfer apparatus 70 to the thermal treatment apparatus 40 and subjected to a pre-bake treatment. The wafer W is thereafter transferred by the wafer transfer apparatus 70 to the delivery apparatus 55.

The wafer W is then transferred by the wafer transfer apparatus 70 to the edge exposure apparatus 43 and subjected to edge exposure processing. The wafer W is thereafter transferred by the wafer transfer apparatus 70 to the delivery apparatus 56.

The wafer W is then transferred by the wafer transfer apparatus 100 to the delivery apparatus 52 and transferred by the shuttle transfer apparatus 80 to the delivery apparatus 62.

The wafer W is thereafter transferred by the wafer transfer apparatus 110 in the interface station 13 to the exposure apparatus 12 and subjected to exposure processing.

Then, the wafer W is transferred by the wafer transfer apparatus 110 from the exposure apparatus 12 to the delivery apparatus 60. Thereafter, the wafer W is transferred by the wafer transfer apparatus 70 to the thermal treatment apparatus 40 and subjected to a post-exposure bake treatment. The wafer W is thereafter transferred by the wafer transfer apparatus 70 to the developing apparatus 30 and developed. After the development ends, the wafer W is transferred by the wafer transfer apparatus 70 to the thermal treatment apparatus 40 and subjected to a post-bake treatment. Thus, a predetermined resist pattern 402 is formed on the neutral layer 401 on the wafer W as illustrated in FIG. 10 (Step S3 in FIG. 8). In this embodiment, the resist pattern 402 has a linear line portion 402a and a linear space portion 402b in planar view and is thus a so-called line-and-space resist pattern. Note that the width of the space portion 402b is set so that an odd number of layers of a hydrophilic polymer 405 and an odd number of layers of a hydrophobic polymer 406 are alternately arranged in the space portion 402b as will be described later.

The wafer W on which the resist pattern 402 has been formed is transferred by the wafer transfer apparatus 70 to the ultraviolet irradiation apparatus 41. In the ultraviolet irradiation apparatus 41, the ultraviolet light is applied to a bared surface of the neutral layer 401 bared from the resist pattern 402 (space portion 402b) as illustrated in FIG. 11. In this event, ultraviolet light having a wavelength of 172 nm is applied. Then, the bared surface of the neutral layer 401 is oxidized and hydrophilized (Step S4 in FIG. 8). Hereinafter, a region of the neutral layer 401 hydrophilized as described above is sometimes called a hydrophilic region 403.

Note that as a result of earnest study of the inventors, it has been found that the wavelength of the ultraviolet light for forming the hydrophilic region 403 in the neutral layer 401 only needs to be 300 nm or less. Concretely, application of the ultraviolet light having a wavelength of 300 nm or less makes it possible to produce active oxygen from the oxygen in a treatment atmosphere, so that the bared surface of the neutral layer 401 is oxidized by the active oxygen and hydrophilized. Note that it is known that for easy production of the active oxygen, it is better to use ozone as the treatment atmosphere. It is also known that especially when the wavelength of the ultraviolet light is 172 nm, it is possible to efficiently produce the active oxygen from oxygen in an atmospheric atmosphere not only in the case of using ozone as the treatment atmosphere but also even in the case of using the atmospheric atmosphere as the treatment atmosphere.

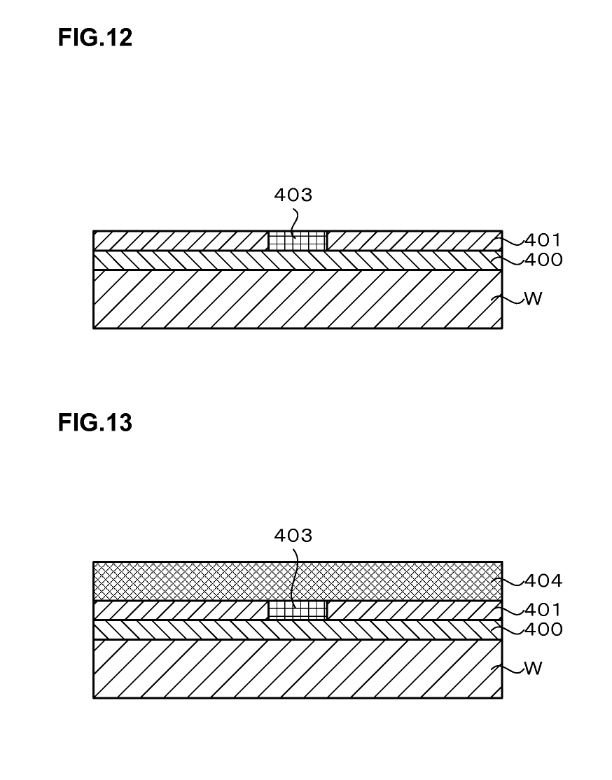

The wafer W is then transferred by the wafer transfer apparatus 70 to the cleaning apparatus 31. In the cleaning apparatus 31, an organic solvent is supplied onto the wafer W, whereby the resist pattern 402 on the wafer W is removed as illustrated in FIG. 12 (Step S5 in FIG. 8). Then, in the neutral layer 401, the surface of the hydrophilic region 403 has a hydrophilic property and the surface of the other region has a neutral property. Thus, the surface of the neutral layer 401 is kept flat. Thereafter, the wafer W is transferred by the wafer transfer apparatus 70 to the delivery apparatus 50.

The wafer W is then transferred by the wafer transfer apparatus 100 to the delivery apparatus 55. The wafer W is then transferred by the wafer transfer apparatus 70 to the block copolymer coating apparatus 35. In the block copolymer coating apparatus 35, a block copolymer 404 is applied onto the neutral layer 401 on the wafer W as illustrated in FIG. 13 (Step S6 in FIG. 8). In this event, the surface of the neutral layer 401 is kept flat, so that the block copolymer 404 is also applied to have a uniform film thickness.

The wafer W is then transferred by the wafer transfer apparatus 70 to the polymer separation apparatus 44 and mounted on the hot plate 172. Along with that, a nitrogen gas is supplied as the non-oxidizing gas into the treatment container 170 of the polymer separation apparatus 44. In this event, the flow rate regulating mechanism 193 is controlled by the control unit 300 to regulate the oxygen concentration in the treatment container 170 to 30 ppm to 50 ppm.

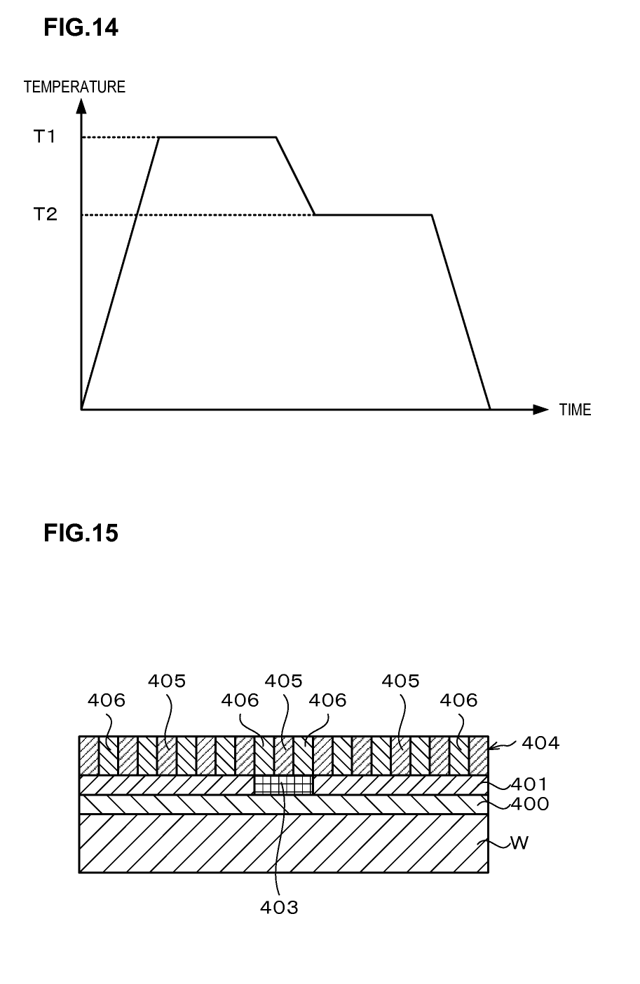

In the polymer separation apparatus 44, the wafer W is first thermally treated by the hot plate 172. In this thermal treatment, for example, a temperature pattern illustrated in FIG. 14 is used. In FIG. 14, the vertical axis indicates temperature of the hot plate 172 and the horizontal axis indicates time of the thermal treatment. As illustrated in FIG. 14, the hot plate 172 is raised in temperature to a first temperature T1 and retained for a fixed time in this thermal treatment. By the thermal treatment at the first temperature T1, the polymers are diffused. The first temperature T1 in this embodiment is, for example, about 350° C. From the viewpoint of diffusing the polymers to elongate the pattern, it is preferable to set the first temperature to a temperature equal to or higher than an order-disorder transition temperature (TOD) of the block copolymer, but normally the polymers of the block copolymer volatilize at a temperature equal to or lower than TOD. Therefore, the first temperature is preferably a temperature as high as possible that is equal to or lower than volatilization temperatures of the polymers.

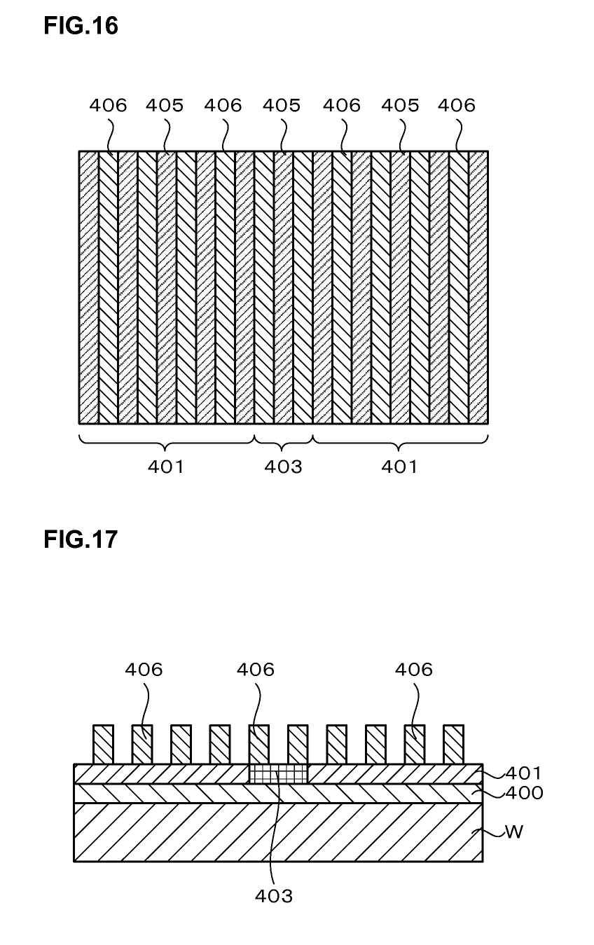

After the wafer W is thermally treated at the first temperature T1 for a predetermined time, the hot plate 172 is lowered in temperature to a second temperature T2 lower than the first temperature T1 and retained for a fixed time as illustrated in FIG. 14. By thermal treatment at the second temperature T2 for a predetermined time, the block copolymer 404 on the wafer W is phase-separated into the hydrophilic polymer 405 and the hydrophobic polymer 406 as illustrated in FIG. 15 and FIG. 16 (Step S7 in FIG. 8). The second temperature in this embodiment is, for example, 170° C. After the wafer W is thermally treated at the second temperature T2 for a predetermined time, the thermal treatment in the polymer separation apparatus 44 is finished, and the hot plate 172 is lowered in temperature.

Here, in the block copolymer 404, the ratio of the molecular weight of the hydrophilic polymer 405 is 40% to 60%, and the ratio of the molecular weight of the hydrophobic polymer 406 is 60% to 40% as described above. Then, at Step S6, the hydrophilic polymer 405 and the hydrophobic polymer 406 are phase-separated into a lamellar structure as illustrated in FIG. 15 and FIG. 16. Further, since the width of the space portion 402b in the resist pattern 402 is formed to be a predetermined width in the above-described Step S3, an odd number of layers, for example, three layers of each of the hydrophilic polymer 405 and the hydrophobic polymer 406 are alternately arranged on the hydrophilic region 403 of the neutral layer 401. Concretely, since the surface of the hydrophilic region 403 has a hydrophilic property, the hydrophilic polymer 405 is arranged at the center on the hydrophilic region 403 and the hydrophobic polymers 406, 406 are arrange on both sides thereof. Then, the hydrophilic polymer 405 and the hydrophobic polymer 406 are alternately arranged also on the other region of the neutral layer 401.

Thereafter, the wafer W is transferred by the wafer transfer apparatus 70 to the delivery apparatus 50, and then transferred by the wafer transfer apparatus 23 in the cassette station 10 to the cassette C on the predetermined mounting plate 21.

After the predetermined treatments are performed on the wafers W in the coating and developing treatment apparatus 2, the cassette C housing the wafers W is transferred out of the coating and developing treatment apparatus 2 and then transferred into the etching treatment apparatus 3.

In the etching treatment apparatus 3, one wafer W is first taken out of the cassette C on the cassette mounting table 212 by the wafer transfer mechanism 210 and transferred into the load-lock apparatus 213a. After the wafer W is transferred into the load-lock apparatus 213a, the inside of the load-lock apparatus 213a is hermetically closed and reduced in pressure. Thereafter, the inside of the load-lock apparatus 213a is communicated with the inside of the transfer room chamber 214 exhausted to a predetermined degree of vacuum. The wafer W is then transferred by the wafer transfer mechanism 215 out of the load-lock apparatus 213a and into the transfer room chamber 214.

The wafer W transferred into the transfer room chamber 214 is then transferred by the wafer transfer mechanism 215 into the etching apparatus 202. In the etching apparatus 202, an etching treatment is performed on the wafer W, and the hydrophilic polymer 405 is selectively removed as illustrated in FIG. 17 to form a predetermined pattern of the hydrophobic polymer 406 (Step S8 in FIG. 8). In this event, since the film thickness of the block copolymer 404 is uniform, the pattern height of the hydrophobic polymer 406 also becomes uniform.

The wafer W is thereafter transferred by the wafer transfer mechanism 215 to the etching apparatus 204. In the etching apparatus 204, the film to be treated on the wafer W is etched using the hydrophobic polymer 406 on the wafer W as a mask. Then, the hydrophobic polymer 406 and the anti-reflection film are removed to form a predetermined pattern in the film to be treated (Step S9 in FIG. 8).

Thereafter, the wafer W is returned again into the transfer room chamber 214 by the wafer transfer mechanism 215. Then, the wafer W is delivered to the wafer transfer mechanism 210 via the load-lock apparatus 213b and housed into the cassette C. Thereafter, the cassette C housing the wafers W is transferred out of the etching treatment apparatus 3, with which a series of wafer treatment end.

According to the above embodiment, the block copolymer 404 on the wafer W is thermally treated in the non-oxidizing gas atmosphere at Step S7, thus making it possible to prevent the hydrophilic polymer 405 and the hydrophobic polymer 406 of the block copolymer 404 from being oxidized.

Accordingly, it is possible to prevent variations of the pattern due to oxidization of the hydrophilic polymer 405 and the hydrophobic polymer 406 and form a predetermined fine pattern on the wafer W. As a result, it is possible to appropriately perform the etching treatment for the film to be treated using the pattern as a mask at Step S9 and to form a predetermined pattern in the film to be treated.

Further, since the block copolymer 404 on the wafer W is thermally treated first at the first temperature T1 at Step S7, the diffusion of the polymers 405, 406 can be promoted to form a longer pattern. Especially when forming a lamellar structure as described above, it is required to array the polymers 405, 406 along the longitudinal direction of the line portion 402a of the resist pattern 402 without variations, and therefore the thermal treatment at the first temperature T1 is effective.

Here, conventionally, etching has also been performed on the neutral layer using a resist pattern as a mask in order to form a region having a hydrophilic property and a region having a neutral property on the wafer W as at Step S4. Then, the surface from which the neutral layer has been removed has a hydrophilic property because the anti-reflection film is bared and the surface on which the neutral layer remains has a neutral property. However, in this case, in order to etch the neutral layer, the wafer W needs to be once transferred out of the coating and developing treatment apparatus 2 and transferred to the etching treatment apparatus 3.

In the above embodiment, the ultraviolet light is applied to the bared surface of the neutral layer 401 in the ultraviolet irradiation apparatus 41 in the coating and developing treatment apparatus 2 at Step S4 to thereby perform surface treatment on the neutral layer 401 so as to hydrophilize it. Here, conventionally, etching has also been performed on the neutral layer using a resist pattern as a mask in order to form a region having a hydrophilic property and a region having a neutral property on the wafer W as at Step S4. Then, the surface from which the neutral layer has been removed has a hydrophilic property because the anti-reflection film is bared and the surface on which the neutral layer remains has a neutral property. However, in this case, in order to etch the neutral layer, the wafer W needs to be once transferred out of the coating and developing treatment apparatus 2 and transferred to the etching treatment apparatus 3. Regarding this point, in this embodiment, the ultraviolet light is applied to hydrophilize the neutral layer 401, so that the above-described transfer of the wafer W from the coating and developing treatment apparatus 2 to the etching treatment apparatus 3 can be omitted. Thus, the wafer treatment at Steps S1 to S7 is performed in one coating and developing treatment apparatus 2. Accordingly, the throughput of the wafer treatment in the substrate treatment system 1 can be improved.

Though the ultraviolet light is applied to the bared surface of the neutral layer 401 to hydrophilize the bared surface at Step S4 in the above embodiment, means for hydrophilizing the bared surface is not limited to this. For example, a hydrophilic film having a hydrophilic property may be formed on the bared surface of the neutral layer 401.

Further, the bared surface of the neutral layer 401 is hydrophilized in the above embodiment, but the bared surface may be hydrophobized as surface treatment. In the case of hydrophobizing the bared surface of the neutral layer 401, the hydrophilic polymer 406 is arranged at the center of the hydrophobized region, and hydrophilic polymers 405, 405 are arranged on both sides thereof. Further, on the wafer W, the hydrophilic polymer 405 and the hydrophobic polymer 406 are alternatively arranged in an arrangement opposite to that in the case of hydrophilizing the bared surface of the neutral layer 401.

Though a so-called dry etching treatment is performed in the etching treatment apparatus 3 when selectively removing the hydrophilic polymer 405 in the above embodiment, the removal of the hydrophilic polymer 405 may be performed by a wet etching treatment.

More specifically, the wafer W for which the block copolymer 404 has been phase-separated at Step S7 is transferred to the ultraviolet irradiation apparatus 41 in place of the etching treatment apparatus 3 at Step S8. Then, the ultraviolet light is applied to the wafer W to cut the bonded chain of polymethyl methacrylate that is the hydrophilic polymer 405 and subject polystyrene that is the hydrophobic polymer 406 to cross-linking reaction. Thereafter, the wafer W is transferred to the cleaning apparatus 31, and, for example, isopropyl alcohol (IPA) is supplied to the wafer W in the cleaning apparatus 31. Thus, the hydrophilic polymer 405 whose bonded chain has been cut by ultraviolet irradiation is dissolved and removed.

In the case of removing the hydrophilic polymer 405 by the so-called dry etching treatment, the selection ratio between the hydrophilic polymer 405 and the hydrophobic polymer 406 is, for example, about 3 to 7:1, so that film thinning of the hydrophobic polymer 406 cannot be avoided. On the other hand, in the case of removing the hydrophilic polymer 405 by the so-called wet etching using an organic solvent, the hydrophobic polymer 406 rarely dissolves in the organic solvent, so that film thinning can be avoided. As a result, when performing the etching treatment on the film to be treated using the pattern of the hydrophobic polymer 406 as a mask in the subsequent step, a sufficient thickness as the mask can be ensured.

Further, removing the hydrophilic polymer 405 by the wet etching makes it possible to omit the above-described transfer of the wafer W from the coating and developing treatment apparatus 2 to the etching treatment apparatus 3. Accordingly, the throughput of the wafer treatment in the substrate treatment system 1 can be improved.

Polymethyl methacrylate is used as the hydrophilic polymer in the above embodiment, but another polymer may be used as the hydrophilic polymer. For example, polydimethylsiloxane (PDMS) can be used as the polymer alternative to polymethyl methacrylate. In the case of using polydimethylsiloxane as the hydrophilic polymer 405, the ratio of a molecular weight of the hydrophilic polymer 405 in the block copolymer 404 is 20% to 40%, and the ratio of a molecular weight of the hydrophobic polymer 406 is 80% to 60%. Note that a substrate treatment system 1 having the same structure as that in the above is used also in this embodiment.

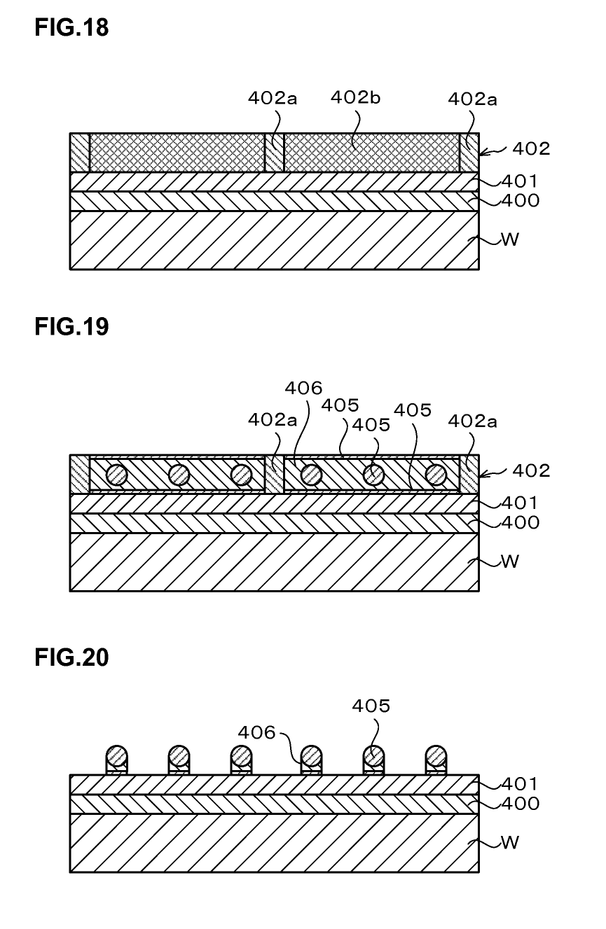

In this case, since the pattern of the polymers 405, 406 is formed using the resist pattern formed at Step S3 as a guide, the surface treatment (hydrophilization) of the neutral layer 401 at Step S4 and the removal of the resist pattern at Step S5 are not performed, but the block copolymer 404 is directly applied to the resist pattern formed at Step S3 as illustrated in FIG. 18 (Step S6).

Thereafter, the block copolymer 404 is thermally treated in the polymer separation apparatus 44 at Step S7. In this event, the inside of the treatment container 170 of the polymer separation apparatus 44 is a non-oxidizing atmosphere. Thus, the block copolymer 404 is phase-separated into the hydrophilic polymer 405 and the hydrophobic polymer 406 in a cylinder structure having a cross-sectional shape that the hydrophobic polymer 406 is sandwiched, at its top and bottom, in between the hydrophilic polymer 405 and the hydrophilic polymer 405 is arranged in a circular shape inside the hydrophobic polymer 406 as illustrated in FIG. 19. The reason why the cylinder structure as illustrated in FIG. 19 is formed is that the surface tension of polydimethylsiloxane used for the hydrophilic polymer 405 is extremely low as compared with that of polystyrene used as the hydrophobic polymer 406, and is phase-separated into a layer shape along the surface of the neutral layer 401. Further, because of the low surface tension, the hydrophilic polymer 405 is phase-separated in a layer shape also on the atmosphere side, so that the hydrophobic polymer 406 is phase-separated in a shape sandwiched in between the hydrophilic polymer 405. The ratio of a molecular weight of the hydrophilic polymer 405 in the block copolymer 404 is 40% to 60%, and the ratio of a molecular weight of the hydrophobic polymer 406 is 60% to 40%, so that the remaining hydrophilic polymer 405 is formed into the cylinder shape inside the hydrophobic polymer 406.

Thereafter, at Step S8, an organic solvent is supplied to the hydrophilic polymer 405 formed in a layer shape on the atmosphere side, for example, in the cleaning apparatus 31 to remove the hydrophilic polymer 405. Then, on the wafer W, the resist pattern 402 and the hydrophobic polymer 406 are selectively removed in the etching treatment apparatus 3 and the hydrophilic polymer 405 and the hydrophobic polymer 406 remaining thereunder form a pattern as illustrated in FIG. 20.

Note that other Steps S1, S2, S9 are the same as those in the above embodiment, and the description thereof will be omitted.

According to this embodiment, it is possible to appropriately phase-separate the block copolymer 404 into the hydrophilic polymer 405 and the hydrophobic polymer 406 in the cylinder structure and thereby appropriately perform etching treatment on the film to be treated.

Though the film to be treated on the wafer W is etched at Step S9 in the above embodiment, the wafer treatment method in the present invention is also applicable in etching the wafer W itself.

Note that though the polymer separation apparatus 44 in the above embodiment has the hot plate 172 and the cooling plate 173 which are arranged inside the treatment container 170, for example, only the hot plate 172 may be arranged inside a treatment container whose inside is closable since the non-oxidizing gas atmosphere is only required at the time when thermally treating the block copolymer 404 on the wafer W by the hot plate 172. In this case, the supply amount of the non-oxidizing gas can be reduced, leading to reduced running cost of the polymer separation apparatus.

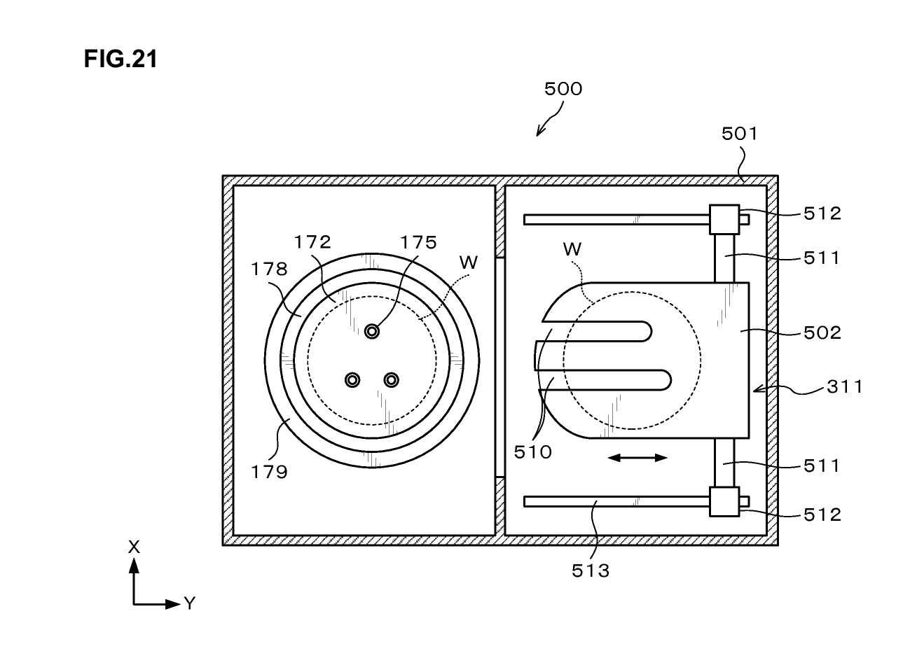

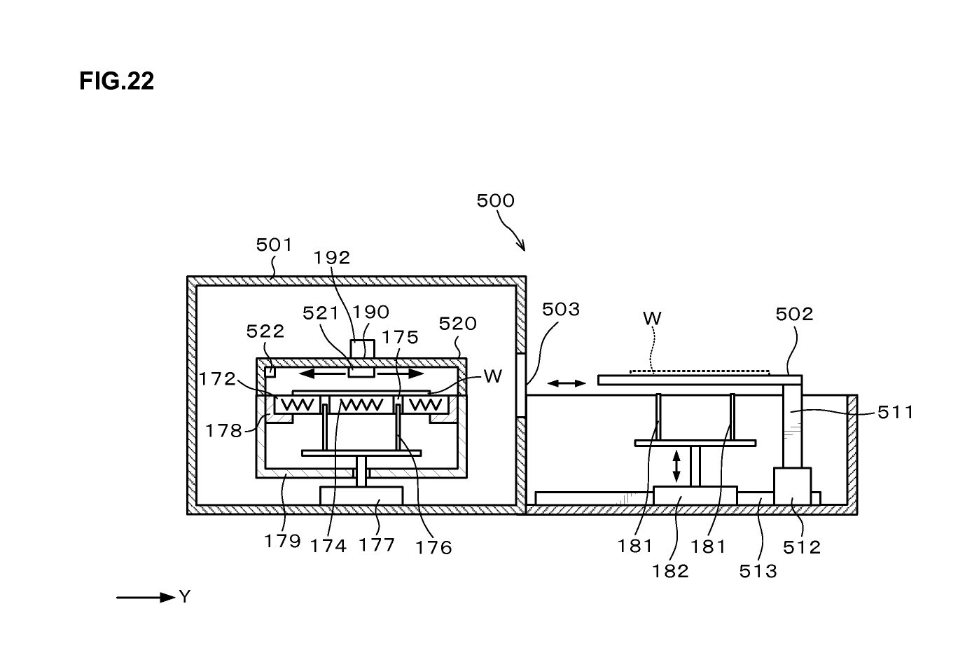

An example of the polymer separation apparatus will be described. FIG. 21 is a longitudinal sectional view illustrating the outline of a configuration of a polymer separation apparatus 500 according to another embodiment, and FIG. 22 is a transverse sectional view illustrating the outline of the configuration of the polymer separation apparatus 500. Note that components having the same configurations as those of the polymer separation apparatus 44 are given the same numerals in FIG. 21, FIG. 22, and the description thereof will be omitted. Main different points from the polymer separation apparatus 44 illustrated in FIG. 6, FIG. 7 will be described below.

The polymer separation apparatus 500 has a casing 501, a cooling plate 502 that mounts and temperature-regulates the wafer W thereon is provided on the wafer transfer apparatus 70 side in the casing 501, and a hot plate 172 is provided on the opposite side to the wafer transfer apparatus 70 side across the cooling plate 502. The casing 501 has a ceiling portion entirely opened on the cooling plate 502 side, and is formed in a container shape having a ceiling only on the hot plate 172 side. Between the cooling plate 502 and the hot plate 172 of the casing 501, a transfer port 503 is formed through which the cooling plate 502 passes.

The cooling plate 502 has an almost square flat plate shape as illustrated in FIG. 22 and has an end face on the hot plate 172 side curved in an arc shape. In the cooling plate 502, two slits 510 are formed along the Y-direction. The slits 510 are formed from the end face on the hot plate 172 side of the cooling plate 502 to the vicinity of the middle portion of the cooling plate 502. The slits 510 can prevent the cooling plate 502 from interfering with the raising and lowering pins 176, 181. Further, in the cooling plate 502, a temperature regulation member (not illustrated) such as a Peltier element is embedded.

The cooling plate 502 is supported on support arms 511 as illustrated in FIG. 21. To the support arms 511, drive units 512 are attached. The drive units 512 are attached on rails 513 extending in the Y-direction. The rails 513 extend from below the cooling plate 502 to the vicinity below the transfer port 503. By means of the drive units 512, the cooling plate 502 can move along the rails 513 to above the hot plate 172. With this configuration, the cooling plate 502 also functions as a transfer mechanism that delivers the wafer W to/from the hot plate 172.

Above the hot plate 172, a cylindrical lid body 520 is provided which has the same diameter as that of the support ring 179. At a ceiling portion and near a central portion of the lid body 520, a gas supply port 190 is formed, and a gas supply source 192 is connected to the gas supply port 190. The gas supply port 190 is provided with a supply nozzle 521 that is formed in an almost disc shape. An outer peripheral portion of the supply nozzle 521 is formed with not-illustrated supply ports which can supply the non-oxidizing gas supplied from the gas supply source 192 radially in a diameter direction of the wafer.

The lid body 520 is formed to freely rise and lower by means of a not-illustrated raising and lowering mechanism, and, for example, the lid body 520 is lowered so that the lower end surface of the lid body 520 comes into contact with the upper surface of the support ring 179 as illustrated in FIG. 22, thereby making a space surrounded by the holding member 178, the support ring 179, the hot plate 172, and the lid body 520 into an almost hermetically closed state. Accordingly, supply of the non-oxidizing gas from the gas supply source 192 in a state that the lid body 520 is in contact with the support ring 179 makes it possible to cover the wafer W on the hot plate 172 with the non-oxidizing gas atmosphere using a minimum amount of non-oxidizing gas. In this case, the holding member 178, the support ring 179, the hot plate 172, and the lid body 520 function as a treatment container whose inside is hermetically closable. Note that, for example, the upper surface of the holding member 178 is formed with a not-illustrated exhaust port which can exhaust the non-oxidizing gas supplied from the gas supply source 192.

Further, for example, the lower surface of the ceiling portion of the lid body 520 is provided with an oxygen concentration detection mechanism 522. The detection result of the oxygen concentration detection mechanism 522 is inputted into the control unit 300.

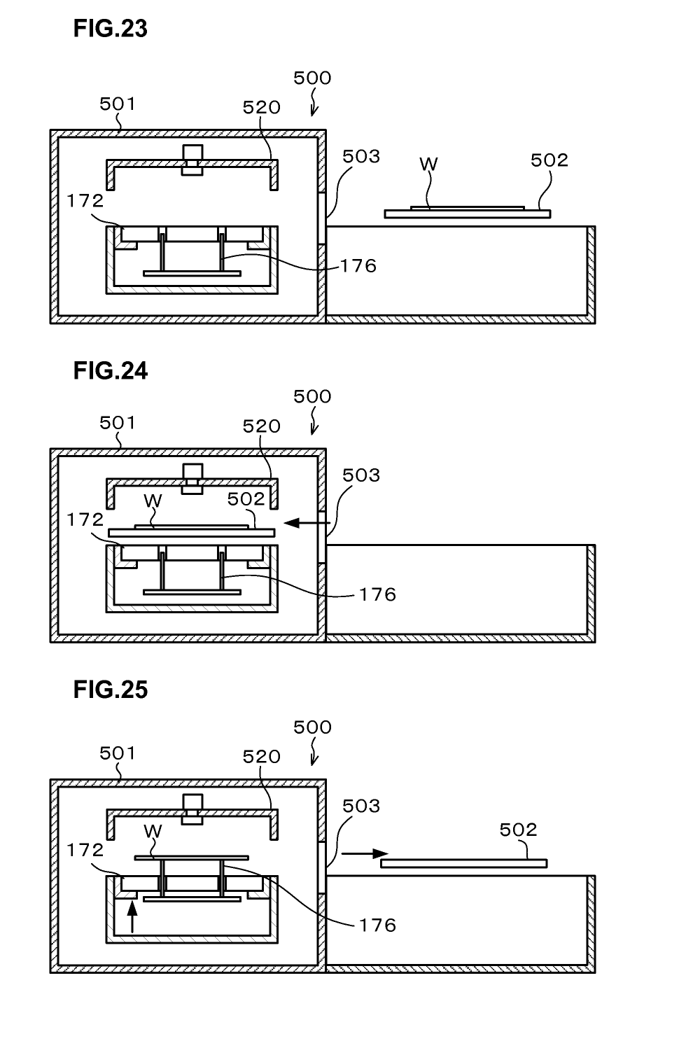

The polymer separation apparatus 500 is configured as described above, and next the treatment on the wafer W in the polymer separation apparatus 500 will be describe using FIG. 23 to FIG. 27. Note that only main devices are illustrated in FIG. 23 to FIG. 27.

For performing the thermal treatment in the polymer separation apparatus 500, the wafer W is first delivered by the wafer transfer apparatus 70 to the cooling plate 502 as illustrated in FIG. 23. Then, the cooling plate 502 is moved in a direction to above the hot plate 172 via the transfer port 503 as illustrated in FIG. 24. In this event, the lid body 520 waists at a position above the hot plate 172 to allow the hot plate 172 to pass below the lid body 520. Further, the hot plate 172 has been beforehand raised in temperature up to the first temperature T1.

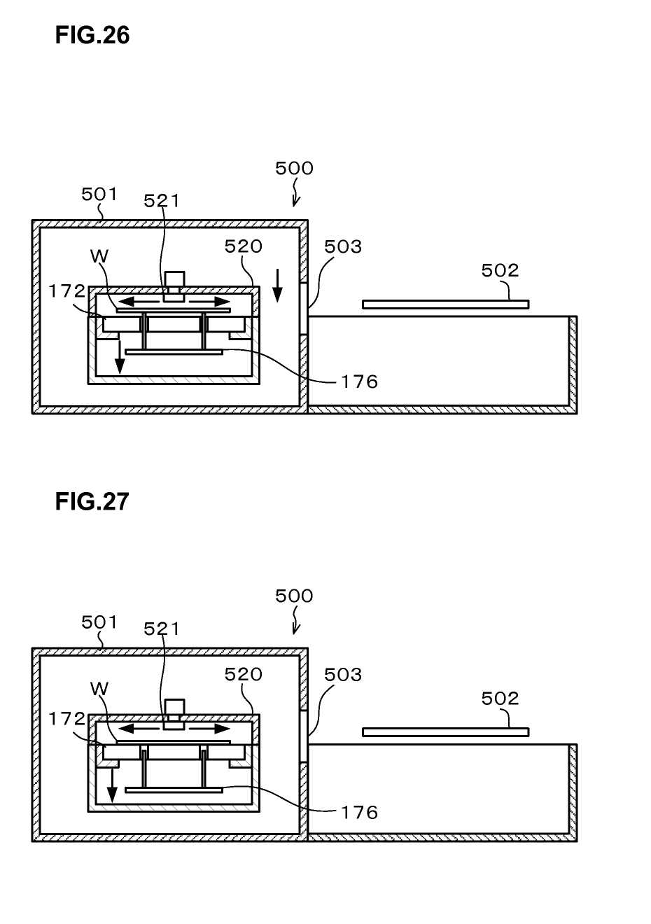

Thereafter, the raising and lowering pins 176 are raised as illustrate in FIG. 25, the wafer W is delivered to the raising and lowering pins 176, and then the cooling plate 502 retreats from below the lid body 520. Thereafter, the lid body 520 lowers so that the lower end surface of the lid body 520 comes into contact with the upper surface of the support ring 179. Thereafter, the nitrogen gas as a non-oxidizing gas is supplied from the supply nozzle 521. The inside of the space surrounded by the lid body 520 and the hot plate 172 is gradually replaced with the non-oxidizing gas. In parallel with the lowering of the lid body 520, the raising and lowering pins 176 lower. In this event, the raising and lowering pins 176 are kept for a fixed time in a state of being separated from the upper surface of the hot plate 172 as illustrated, for example, in FIG. 26. The distance between the wafer W and the hot plate 172 in this event is adjusted so that the temperature of the wafer W does not exceed 200° C. Thus, the wafer W is mounted on the hot plate 172 before the atmosphere around the wafer W is replaced with the non-oxidizing gas, thereby making it possible to prevent oxidization of the hydrophilic polymer 405 and the hydrophobic polymer 406 of the block copolymer 404.

Thereafter, it is determined that the oxygen concentration becomes, for example, 50 ppm or less, for example, by the control unit 300 on the basis of the value detected by the oxygen concentration detection mechanism 522, the raising and lowering pins 176 are further lowered so that the wafer W is mounted on the hot plate 172 as illustrated in FIG. 27. Note that the time for keeping the state that the wafer W is separated from the upper surface of the hot plate 172 by the predetermined distance may be decided based on the measurement result by the oxygen concentration detection mechanism 522, or may be decided by obtaining the time when the oxygen concentration becomes 50 ppm or less on the basis of the examination or the like performed beforehand. Then, after the wafer W is heated for a predetermined time at the first temperature T1 and the second temperature T2, the lid body 520 and the raising and lowering pins 176 are raised, with which the thermal treatment in the polymer separation apparatus 500 ends. Subsequently, devices operate in a reverse order to that in FIG. 23 to FIG. 25 and thereby deliver the wafer W to the cooling plate 502. Thereafter, the wafer W is cooled by the cooling plate 502 for a predetermined time and thereby temperature-regulated, with which the treatment in the polymer separation apparatus 500 ends.

According to the polymer separation apparatus 500, the non-oxidizing gas is supplied only into the space surrounded by the lid body 520 and the hot plate 172, so that the consumption of the non-oxidizing gas can be reduced to reduce the running cost as compared with the polymer separation apparatus 44.

Further, since the wafer W is kept for a fixed time in a state of being separated from the upper surface of the hot plate 172 by the predetermined distance, more specifically, the wafer W is not mounted on the hot plate 172 until the oxygen concentration in the space surrounded by the lid body 520 and the hot plate 172 becomes a predetermined value, thereby making it possible to prevent oxidization of the hydrophilic polymer 405 and the hydrophobic polymer 406 of the block copolymer 404.

Note that the neutral layer 401 is used as a base film of the block copolymer 404 in the above embodiment, but the kind of the base film is not limited to the above embodiment. For example, polystyrene being a hydrophobic polymer heated at a predetermined temperature, for example, 350° C. and thereby cross-linked may be used as the base film.

Note that the neutral layer 401 or polystyrene used as the base film are oxidized due to heating, variations occur in physical properties of the surface state. As a result, in the case of the neutral layer 401, a neutral portion and a non-neutral portion are produced on the neutral layer 401, whereas in the case of the polystyrene, a portion having a hydrophobic property and a portion having no hydrophobic property are produced. Accordingly, to more efficiently suppress the oxidization of the neutral layer 401 or the polystyrene film used as the base film, in the heat treatment performed after Step S2 and before Step S3, for example, a base film forming apparatus that performs heat treatment in the non-oxidizing gas atmosphere may be used to perform heat treatment. As the base film forming apparatus, the above-described polymer separation apparatus 44 or polymer separation apparatus 500 may be used, or another thermal treatment apparatus having the same configuration as that of the polymer separation apparatus 44, 500 may be used. Note that when the oxidization of the base film is a dominant cause of variations of the pattern, for example, only the heat treatment performed in the base film forming apparatus after Step S2 and before Step S3 may be performed in the non-oxidizing gas atmosphere, and the heat treatment at Step S7 may be performed in an atmosphere other than the non-oxidizing gas atmosphere.

Further, when applying polystyrene to the wafer W, a nozzle that supplies polystyrene may be provided in the solution treatment apparatus such as the neutral layer forming apparatus 33, or a polystyrene coating apparatus that applies polystyrene to form a polystyrene film may be separately provided. Note that the configuration of the polystyrene coating apparatus may be the same as that of the other solution treatment apparatus such as the neutral layer forming apparatus 33 or the block copolymer coating apparatus 35.

Preferred embodiments of the present invention have been described above with reference to the accompanying drawings, but the present invention is not limited to the embodiments. It should be understood that various changes and modifications are readily apparent to those skilled in the art within the scope of the spirit as set forth in claims, and those should also be covered by the technical scope of the present invention. The present invention is not limited to the embodiments but can take various forms. The present invention is also applicable to the case where the substrate is a substrate other than the wafer, such as an FPD (Flat Panel Display), a mask reticle for a photomask or the like.

### INDUSTRIAL APPLICABILITY

The present invention is useful in treating a substrate, for example, using a block copolymer containing a hydrophilic polymer having a hydrophilic property and a hydrophobic polymer having a hydrophobic property.

### EXPLANATION OF CODES

1 substrate treatment system
2 coating and developing treatment apparatus
3 etching treatment apparatus
30 developing apparatus
31 cleaning apparatus
32 anti-reflection film forming apparatus
33 neutral layer forming apparatus
34 resist coating apparatus
35 block copolymer coating apparatus
40 thermal treatment apparatus
41 ultraviolet irradiation apparatus
42 adhesion apparatus
43 edge exposure apparatus
44 polymer separation apparatus
202 to 205 etching apparatus
300 control unit
400 anti-reflection film
401 neutral layer
402 resist pattern
402a line portion
402b, 402c space portion
403 hydrophilic region
404 block copolymer
405 hydrophilic polymer
406 hydrophobic polymer
W wafer

1. A method of treating a substrate using a block copolymer containing a first polymer and a second polymer, the method comprising:
a block copolymer coating step of applying the block copolymer onto a substrate or a base film applied on the substrate; and
a polymer separation step of phase-separating the block copolymer into the first polymer and the second polymer by thermally treating the block copolymer on the substrate in a non-oxidizing gas atmosphere.

2. The substrate treatment method according to claim 1,
wherein in the polymer separation step, heating is performed at a first temperature to diffuse the first polymer and the second polymer of the block copolymer, and then heating is performed at a second temperature lower than the first temperature to phase-separate the first polymer and the second polymer.

3. The substrate treatment method according to claim 2, further comprising:
a polymer removal step of selectively removing either the first polymer or the second polymer from the phase-separated block copolymer.

4. The substrate treatment method according to claim 3,
wherein in the polymer removal step, either the first polymer or the second polymer is selectively removed by a plasma etching treatment or supply of an organic solvent.

5. The substrate treatment method according to claim 1,
wherein the first polymer is a hydrophilic polymer having a hydrophilic property, and
wherein the second polymer is a hydrophobic polymer having a hydrophobic property.

6. The substrate treatment method according to claim 5,
wherein the hydrophilic polymer is polymethyl methacrylate, and
wherein the hydrophobic polymer is polystyrene.

7. The substrate treatment method according to claim 5,
wherein the hydrophilic polymer is polydimethylsiloxane, and
wherein the hydrophobic polymer is polystyrene.

8. The substrate treatment method according to claim 6,
wherein the base film is a neutral layer formed by applying a neutralizing agent having an intermediate affinity to the hydrophilic polymer and the hydrophobic polymer onto the substrate before the block copolymer coating step and heating the neutralizing agent at a predetermined temperature in a non-oxidizing gas atmosphere.

9. The substrate treatment method according to claim 1,
wherein in the polymer separation step, a mounting surface of a mounting table is heated for a predetermined period with the substrate separated by a predetermined distance from the mounting table, the mounting table provided in a treatment container whose inside is hermetically closable and configured to mount the substrate on the mounting surface and thermally treat the substrate thereon, and
after a lapse of the predetermined period, the substrate is mounted on the mounting table and heated.

10. The substrate treatment method according to claim 9,
wherein in the polymer separation step, an oxygen concentration in the treatment container is measured, and
after the oxygen concentration in the treatment container becomes a predetermined concentration or lower, the substrate is mounted on the mounting table and heated.

11. The substrate treatment method according to claim 6,
wherein the base film is formed by applying polystyrene onto the substrate before the block copolymer coating step and heating the polystyrene at a predetermined temperature in a non-oxidizing gas atmosphere.

12. The substrate treatment method according to claim 11,
wherein the heating of the polystyrene at a predetermined temperature is performed by
heating a mounting surface of a mounting table for a predetermined period with the substrate separated by a predetermined distance from the mounting table, the mounting table provided in a treatment container whose inside is hermetically closable and configured to mount the substrate on the mounting surface and thermally treat the substrate thereon, and
after a lapse of the predetermined period, mounting and heating the substrate on the mounting table.

13. The substrate treatment method according to claim 12,
wherein in the heating of the polystyrene at a predetermined temperature,
an oxygen concentration in the treatment container is measured, and
after the oxygen concentration in the treatment container becomes a predetermined concentration or lower, the substrate is mounted on the mounting table and heated.

14. A computer-readable storage medium storing a program running on a computer of a control unit controlling a substrate treatment system to cause the substrate treatment system to perform a substrate treatment method of treating a substrate using a block copolymer containing a first polymer and a second polymer, the substrate treatment method comprising:
a block copolymer coating step of applying the block copolymer onto a substrate or a base film applied on the substrate; and
a polymer separation step of phase-separating the block copolymer into the first polymer and the second polymer by thermally treating the block copolymer on the substrate in a non-oxidizing gas atmosphere.

15. A system for treating a substrate using a block copolymer containing a first polymer and a second polymer, the system comprising:
a block copolymer coating apparatus that applies the block copolymer onto a substrate or a base film applied on the substrate; and
a polymer separation apparatus that phase-separates the block copolymer into the first polymer and the second polymer by thermally treating the block copolymer on the substrate in a non-oxidizing gas atmosphere.

16. The substrate treatment system according to claim 15,
wherein in the polymer separation apparatus, heating is performed at a first temperature to diffuse the first polymer and the second polymer of the block copolymer, and then heating is performed at a second temperature lower than the first temperature to phase-separate the first polymer and the second polymer.

17. The substrate treatment system according to claim 16, further comprising:
a polymer removing apparatus that selectively removes either the first polymer or the second polymer from the phase-separated block copolymer.

18. The substrate treatment system according to claim 17,
wherein the polymer removing apparatus is a plasma etching treatment apparatus, or a solvent supply apparatus that supplies an organic solvent to selectively remove either the first polymer or the second polymer.

19. The substrate treatment system according to claim 15,
wherein the first polymer is a hydrophilic polymer having a hydrophilic property, and
wherein the second polymer is a hydrophobic polymer having a hydrophobic property.

20. The substrate treatment system according to claim 19,
wherein the hydrophilic polymer is polymethyl methacrylate, and
wherein the hydrophobic polymer is polystyrene.

21. The substrate treatment system according to claim 19,
wherein the hydrophilic polymer is polydimethylsiloxane, and
wherein the hydrophobic polymer is polystyrene.

22. The substrate treatment system according to claim 20,
wherein the base film is formed by heating a neutral layer having an intermediate affinity to the hydrophilic polymer and the hydrophobic polymer at a predetermined temperature, and
wherein the substrate treatment system further comprises:
a neutral layer forming apparatus that applies a neutralizing agent onto the substrate before the block copolymer is applied, to form a neutral layer; and
a base film forming apparatus that heats the neutral layer at a predetermined temperature to form the base film,
wherein the base film forming apparatus comprises:
a treatment container whose inside is hermetically closable;
a mounting table that is provided in the treatment container and mounts the substrate thereon;
a heating mechanism that heats a mounting surface for the substrate of the mounting table;
a gas supply source that supplies a non-oxidizing gas into the treatment container;
a raising and lowering mechanism that holds the substrate and relatively moves up and down the held substrate with respect to the mounting surface of the mounting table;
a transfer mechanism that delivers the substrate to/from the raising and lowering mechanism; and
a control unit that controls the gas supply source to supply the non-oxidizing gas into the treatment container and controls the transfer mechanism to deliver the substrate to the raising and lowering mechanism, then controls the raising and lowering mechanism and the heating mechanism to heat the mounting surface of the mounting table for a predetermined period with the substrate separated from the mounting surface of the mounting table by a predetermined distance, and further controls, after a lapse of the predetermined period, the raising and lowering mechanism and the heating mechanism to mount and heat the substrate on the mounting table.

23. The substrate treatment system according to claim 15,
wherein the polymer separation apparatus comprises:
a treatment container whose inside is hermetically closable;
a mounting table that is provided in the treatment container and mounts the substrate thereon;
a heating mechanism that heats a mounting surface for the substrate of the mounting table;
a gas supply source that supplies a non-oxidizing gas into the treatment container;
a raising and lowering mechanism that holds the substrate and relatively moves up and down the held substrate with respect to the mounting surface of the mounting table;
a transfer mechanism that delivers the substrate to/from the raising and lowering mechanism; and
a control unit that controls the gas supply source to supply the non-oxidizing gas into the treatment container and controls the transfer mechanism to deliver the substrate to the raising and lowering mechanism, then controls the raising and lowering mechanism and the heating mechanism to heat the mounting surface of the mounting table for a predetermined period with the substrate separated from the mounting surface of the mounting table by a predetermined distance, and further controls, after a lapse of the predetermined period, the raising and lowering mechanism and the heating mechanism to mount and heat the substrate on the mounting table.

24. The substrate treatment system according to claim 23,
wherein the polymer separation apparatus further comprises an oxygen concentration detection mechanism that detects an oxygen concentration in the treatment container, and
wherein the control unit controls the raising and lowering mechanism and the heating mechanism to mount and heat the substrate on the mounting table after the oxygen concentration in the treatment container becomes a predetermined concentration or lower.

25. The substrate treatment system according to claim 20,
wherein the base film is polystyrene heated at a predetermined temperature,
wherein the substrate treatment system further comprises:
a polystyrene coating apparatus that applies polystyrene onto the substrate before the block copolymer is applied, to form a polystyrene film; and
a base film forming apparatus that heats the polystyrene film at a predetermined temperature to form the base film, and
wherein the base film forming apparatus comprises:
a treatment container whose inside is hermetically closable;
a mounting table that is provided in the treatment container and mounts the substrate thereon;
a heating mechanism that heats a mounting surface for the substrate of the mounting table;
a gas supply source that supplies a non-oxidizing gas into the treatment container;
a raising and lowering mechanism that holds the substrate and relatively moves up and down the held substrate with respect to the mounting surface of the mounting table;
a transfer mechanism that delivers the substrate to/from the raising and lowering mechanism; and
a control unit that controls the gas supply source to supply the non-oxidizing gas into the treatment container and controls the transfer mechanism to deliver the substrate to the raising and lowering mechanism, then controls the raising and lowering mechanism and the heating mechanism to heat the mounting surface of the mounting table for a predetermined period with the substrate separated from the mounting surface of the mounting table by a predetermined distance, and further controls, after a lapse of the predetermined period, the raising and lowering mechanism and the heating mechanism to mount and heat the substrate on the mounting table.

26. The substrate treatment system according to claim 25,
wherein the polymer separation apparatus further comprises an oxygen concentration detection mechanism that detects an oxygen concentration in the treatment container, and
wherein the control unit controls the raising and lowering mechanism and the heating mechanism to mount and heat the substrate on the mounting table after the oxygen concentration in the treatment container becomes a predetermined concentration or lower.
